(19) United States
(12) Patent Application Publication
(10) Pub. No.: US 2020/0258759 A1
(43) Pub. Date: Aug. 13, 2020

(54) STRUCTURES FOR CONDUCTING HEAT WITH A PACKAGED DEVICE AND METHOD OF PROVIDING SAME

(71) Applicant: Intel Corporation, Santa Clara, CA (US)

(72) Inventors: Wilfred GOMES, Portland, OR (US); Ravindranath V. MAHAJAN, Chandler, AZ (US); Ram S. VISWANATH, Phoenix, AZ (US)

(21) Appl. No.: 16/635,539

(22) PCT Filed: Sep. 29, 2017
(86) PCT No.: PCT/US2017/054618

§ 371 Date: Jan. 30, 2020

(51) Int. Cl. H01L 21/48; H01L 23/31; H01L 21/56; H01L 23/367

(52) U.S. Cl. CPC H01L 21/4882; H01L 23/3675; H01L 21/56; H01L 23/3121

(57) ABSTRACT

Techniques and mechanisms for conducting heat with a packaged integrated circuit (IC) device. In an embodiment, the IC device comprises a package substrate and one or more IC dies coupled thereto, where a thermal conductor of the IC device extends through the package substrate. A thermal conductivity of the thermal conductor is more than 20 Watts per meter per degree Kelvin (W/mK). In another embodiment, thermal conductor further extends at least partially through a mold compound disposed on the one or more IC dies.

### TECHNICAL FIELD

Embodiments of the invention relate generally to heat conduction in a circuit device and more particularly, but not exclusively, to a thermal conductor which extends at least in part through a package substrate.

### BACKGROUND

Integrated circuits are typically housed within a package that is soldered to a printed circuit board. The integrated circuit generates heat which is typically moved away from the package by an external fan. The packages are typically constructed from a ceramic or plastic material which has a relatively low thermal coefficient of conductivity. The high thermal impedance of the package produces an undesirable temperature differential between the ambient air and the junction temperatures of the integrated circuit.

Highly functional integrated circuits such as microprocessors generate a large amount of heat which must be removed while maintaining the temperatures of such circuits below a critical value. As successive generations of packaged integrated circuit (IC) devices continue to scale in size and operational frequency, there is expected to be an increasing premium placed on incremental improvements to thermal conduction within or from such packaged IC devices.

### BRIEF DESCRIPTION OF THE DRAWINGS

The various embodiments of the present invention are illustrated by way of example, and not by way of limitation, in the figures of the accompanying drawings and in which:

FIGS. 1A-1B show a cross-sectional side view and a perspective view each of an integrated circuit (IC) device according to an embodiment.

FIG. 2 is a flow diagram illustrating elements of a method to provide a thermal conductor of an IC device according to an embodiment.

FIGS. 3A-3F show various cross-sectional views during respective stages of processing to fabricate a thermal conductor according to an embodiment.

FIGS. 4A-4C show various views of an IC device including a thermal conductor according to an embodiment.

FIGS. 5A-5B show an assembly view and an assembled view each of an IC device including a thermal conductor according to an embodiment.

FIG. 6 is a functional block diagram illustrating elements of a computing device in accordance with one embodiment.

FIG. 7 is a functional block diagram illustrating elements of an exemplary computer system, in accordance with an embodiment.

### DETAILED DESCRIPTION

Embodiments discussed herein variously provide techniques and mechanisms for conducting heat within and/or from a packaged IC device. The IC device may include a package substrate, one or more IC dies coupled to the package substrate, and a thermal conductor which extends through the package substrate. The thermal conductor may further extend above the package substrate—e.g., at least partially through a mold compound which is disposed on the one or more IC dies. The thermal conductor may include any of a variety of high thermal conductivity materials—e.g., having a thermal conductivity at room temperature (25° C.) of more than 20 Watts per meter per degree Kelvin (W/mK) and, in some embodiments, more than 50 W/mK. Examples of such materials include, but are not limited to, copper (Cu), copper tungsten (CuW), aluminum nitride (AlN), beryllium oxide (BeO) and molybdenum (Mo).

The technologies described herein may be implemented in one or more electronic devices. Non-limiting examples of electronic devices that may utilize the technologies described herein include any kind of mobile device and/or stationary device, such as cameras, cell phones, computer terminals, desktop computers, electronic readers, facsimile machines, kiosks, laptop computer, netbook computers, notebook computers, internet devices, payment terminals, personal digital assistants, media players and/or recorders, servers (e.g., blade server, rack mount server, combinations thereof, etc.), set-top boxes, smart phones, tablet personal computers, ultra-mobile personal computers, wired telephones, combinations thereof, and the like. More generally, the technologies described herein may be employed in any of a variety of electronic devices including a packaged IC device which includes a package substrate and a thermal conductor extending therethrough.

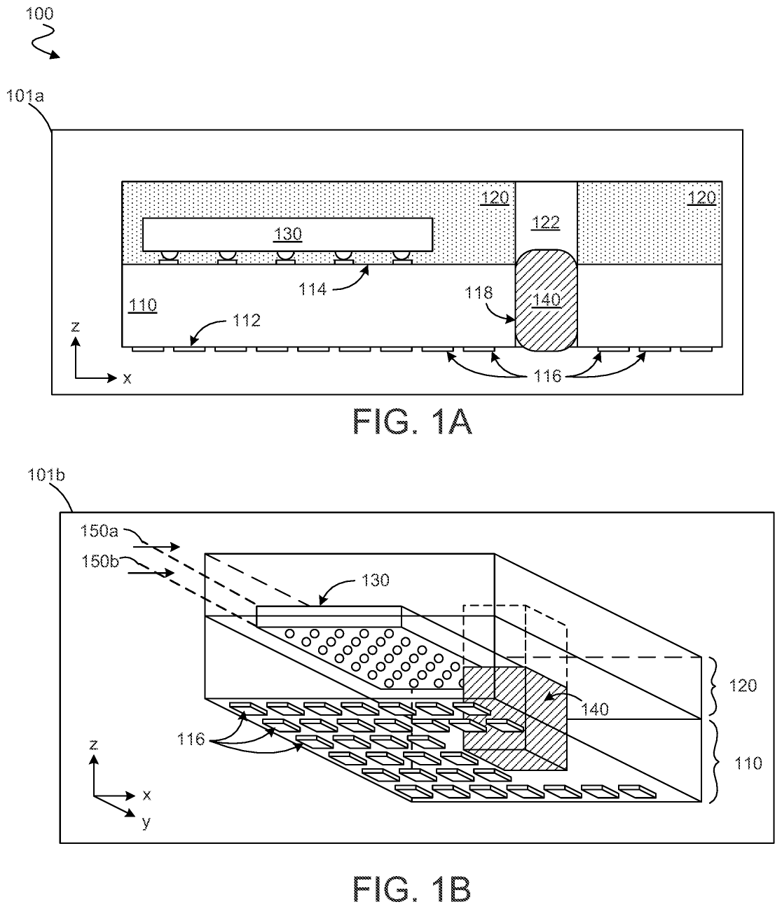

FIG. 1A shows an orthogonal view 101a of features of a IC device 100 including structures to facilitate heat conduction according to an embodiment. IC device 100 is one example of an embodiment wherein a packaged device includes a thermal conductor that extends through a package substrate and, in some embodiments, further extends through or past one or more structures disposed, directly or indirectly, on the package substrate.

In the example embodiment shown, IC device 100 includes a package substrate 110 and one or more IC dies (such as the illustrative IC die 130 shown) which are wire bonded, flip-chip attached or otherwise coupled to package substrate 110. In some embodiments, a mold compound 120 is disposed over some or all of the one or more IC dies. FIG. 1B illustrates a perspective view 101b of IC device 100, wherein respective portions of package substrate 110 and mold compound 120 are shown as being transparent merely to illustrate structures disposed therein.

The one or more dies of IC device 100 may include any of a variety of one or more integrated circuit components including, but not limited to, a central processing unit, graphics processor, memory, memory controller, controller hub and/or the like. For example, IC die 130 may comprise a system-on-chip (SoC). However, other embodiments are not limited with respect to a particular functionality that might be provided with the one or more IC dies.

Package substrate 110 illustrates any of a variety of structures which include a ceramic, organic, and/or other suitable insulator material, including but not limited to an organic laminated glass-weave polymer, to provide physical support to IC die 130. Conductors (not shown) of package substrate 110 may variously extend through such insulator material to facilitate routing of one or more voltages or signals to and/or from IC die 130. For example, conductive contacts 116 (e.g., including metal pads) formed in or on a side 112 of package substrate 110 may be coupled to other conductive contacts in or on an opposite side 114 of package substrate 110, where said other conductive contacts are to be coupled by microbumps, wires and/or other conductors to IC die 130. Contacts 116 may form at least in part a hardware interface at side 112, the hardware interface to couple IC device 100 to any of various other devices such as a printed circuit board, another packaged device, or the like. Package substrate 110 may be a coreless substrate, for example, although some embodiments are not limited in this regard.

To facilitate heat management with IC device 100, some embodiments provide a thermal conductor 140 which extends at least through package substrate 110 (e.g., to each of sides 112, 114). For example, package substrate 110 may form a sidewall structure 118 which surrounds (and in some embodiments, adjoins) thermal conductor 140—e.g., where sidewall structure 118 extends to each of sides 112, 114. Sidewall structure 118 may define at least in part a hole structure (such as the illustrative hole 122 shown) to accommodate thermal conductor 140—e.g., where package substrate 110 surrounds thermal conductor 140 at least in a plane which is parallel to the x-y plane of the xyz-coordinate system shown. Although hole 122 is shown as also extending entirely through mold compound 120, other embodiments are not limited in this regard. For example, hole 122 may instead extend only between sides 112, 114, where mold compound 120, an IC die and/or other structure defines an end of hole 122 at side 114.

Although some embodiments are not limited in this regard, some or all of the one or more IC dies of IC device 100 may be disposed side-by-side entirely within a first plane 150a and a second plane 150b of the IC device 100 which, for example, are both parallel to the x-y plane shown. In such an embodiment, thermal conductor 140 may extend through one or both of the first plane 150a and the second plane 150b—e.g., wherein a portion of thermal conductor 140 is disposed between two such side-by-side IC dies. Although it is shown as extending only partially through mold compound 120, thermal conductor 140 may alternatively extend entirely through hole 122 to form or couple to a second thermal interface contact (not shown) at a side of mold compound 120—e.g., at a top exterior of IC device 100. In some embodiments, thermal conductor 140 forms one or more fin structures which each extend through package substrate 110—e.g., where said fin structures each extend from a planar thermal conductor structure (not shown) at side 112.

Thermal conductor 140 may include a metal or ceramic that exhibits thermal conductivity at room temperature which is more than 20 W/mK (e.g., wherein said thermal conductivity is more than 50 W/mK and, in some embodiments, more than 70 W/mK). Thermal conductor 140 may be a structure other than any electrical conductor that is coupled to communicate a signal with the one or more IC dies. Alternatively or in addition, thermal conductor 140 may be a structure other than any electrical conductor that is coupled to provide a voltage with the one or more IC dies. In some embodiments, thermal conductor 140 forms (or is coupled to) a structure, at or near side 112, which is to function as a contact region for providing an interface by which heat is to be conducted to or from IC device 100. For brevity, such a structure is referred to herein as a thermal interface contact.

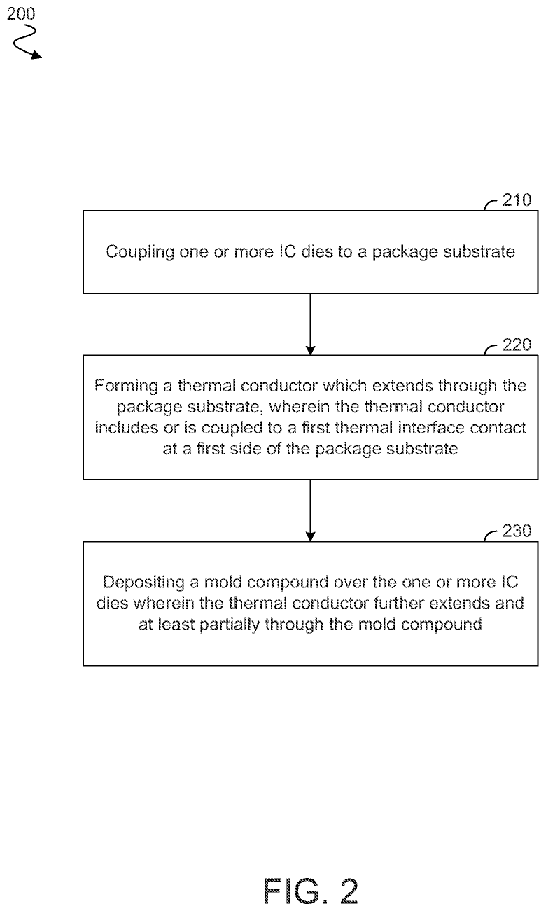

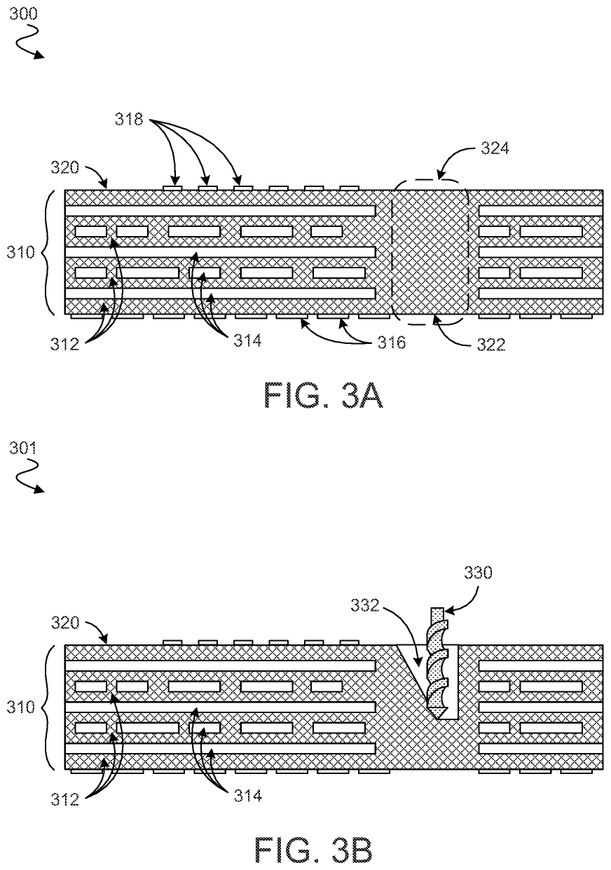

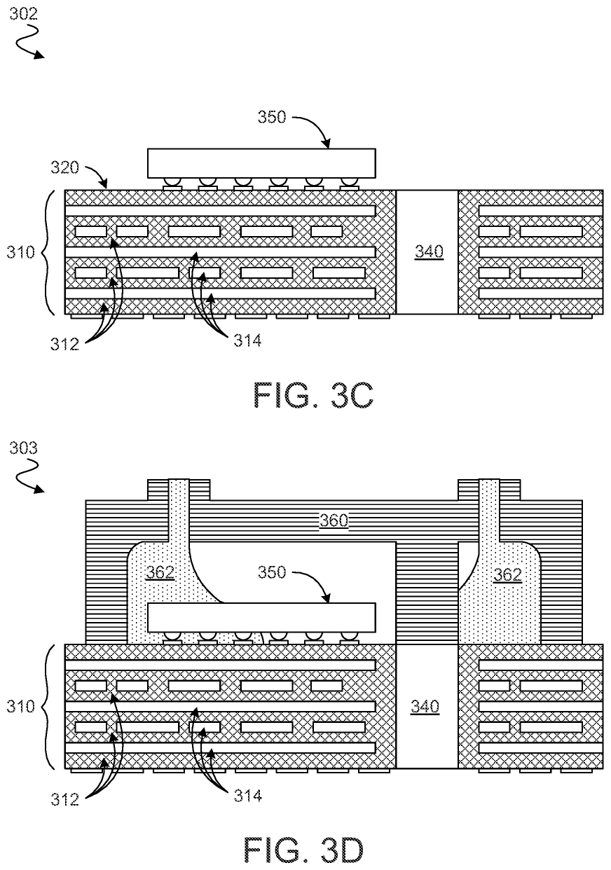

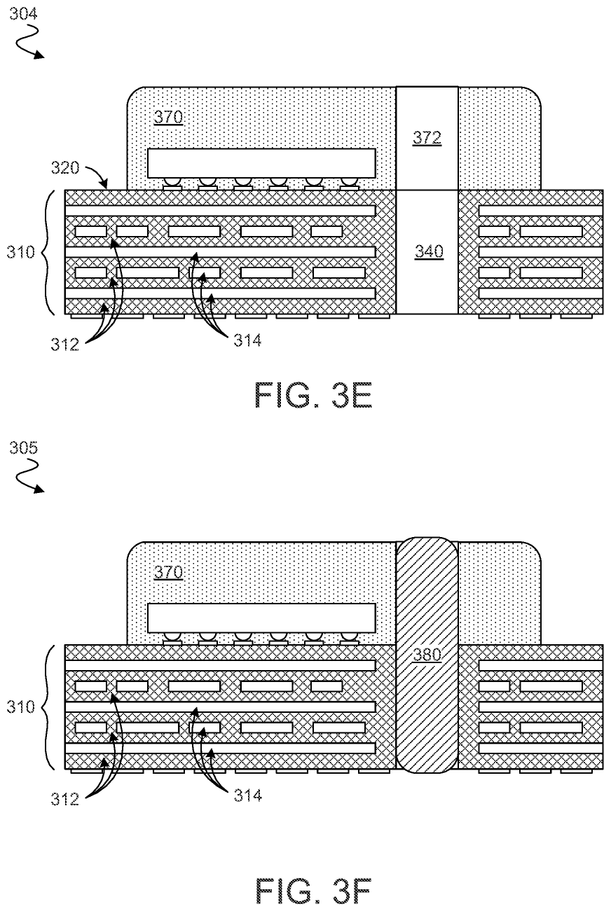

FIG. 2 shows features of a method 200 to provide thermal conductor structures according to an embodiment. Method 200 may provide some or all of the structures of IC device 100. To illustrate certain features of various embodiments, method 200 is described herein with reference to the formation of structures shown in FIGS. 3A-3F. However, such description may be extended to apply to the formation of additional structure and/or alternative structures, in different embodiments.

In the example embodiment shown, method 200 includes, at 210, coupling one or more integrated circuit (IC) dies to a package substrate. For example, FIGS. 3A-3F show, in six respective cross-sectional views, various stages 300-305 of processing to provide a thermal conductor structure of an IC device according to an embodiment. As shown at stage 300 in FIG. 3A, a package substrate 310 may include a dielectric 312 and metal layers 314 variously extending in parallel with one another through respective levels of dielectric 312. Metal layers 314 may variously facilitate communication of signals and/or voltages through package substrate 310. For example, contacts 316 may be variously disposed in or on a side 322 of package substrate 310, where other contacts 318 are variously disposed in or on a side 320 of package substrate 310 which is opposite side 322. Conductive paths of package substrate 310, variously formed at least in part with metal layers 314 and via structures (not shown) coupled thereto, may each interconnect a respective one of contacts 316 with a respective one of contacts 318. In such an embodiment, one or more regions of package substrate 310 (e.g., including the illustrative region 324 shown) may be devoid of any conductor of metal layers 314, contacts 316 and/or contacts 318. Region 324 may thus accommodate the subsequent formation of a hole which extends through package substrate 310.

For example, as shown at stage 301 in FIG. 3B, a drill 330 (or alternatively, a laser) may remove portions of dielectric 312 from package substrate 310 to form a recess 332. As shown at stage 302 in FIG. 3C, further removal of portions of dielectric 312 may extend recess 332 until the formation of a hole structure 340 which extends to each of sides 320, 322. Hole 340 may have an average cross-sectional area (e.g., in the x-y plane shown in FIG. 1) which is at least 500 square micrometers (μm²). For example, such an average cross-sectional area may be at least 1000 μm² and, in some embodiments, at least 1 square millimeter (mm²). In an embodiment, one or more IC dies (such as the illustrative IC die 350 shown) may then be wire bonded, flip-chip attached or otherwise coupled to package substrate via contacts 318.

Referring again to FIG. 2, method 200 may further comprise, at 220, forming a thermal conductor which extends through the package substrate. In some embodiments, method 200 further comprises, at 230, depositing a mold compound over the one or more IC dies—e.g., wherein the thermal conductor further extends at least partially through the mold compound. For example, as shown in FIG. 3D at stage 303, packaging of the IC device may include a packaging compound 362 being injection molded or otherwise deposited on one or both of IC die 350 and package substrate 310. Packaging compound 362 may include any of a variety of resinous, plastic, ceramic and/or other materials adapted, for example, from conventional circuit packaging techniques.

In the example embodiment shown, a mold 360 is used to shape packaging compound 362 during deposition thereof. Mold 360 may be configured to prevent packaging compound 362 from flowing into hole structure 340. In some embodiments, mold 360 is also shaped to extend the length of a hole which includes hole structure 340. For example, as shown at stage, 304 in FIG. 3E, packaging compound 362 may be subsequently cured to form a package 370. Due at least in part to a shape of mold 360, package 370 may form a hole structure 372 that is above hole structure 340—e.g., wherein hole structures 340, 372 are aligned to define at least in part a larger hole which extends through the packaged IC device.

Subsequently, as shown at stage 305 in FIG. 3F, a thermal conductor 380 may be disposed in the hole which is defined with hole structures 340, 372. By way of illustration and not limitation, an electroplating process or an electroless plating processes may be performed to form thermal conductor 380 in the hole. Alternatively, thermal conductor 380 may be pressed, pick placed or otherwise deposited into the hole—e.g., where an epoxy or other adhesive material affixes thermal conductor 380 to sidewall structures variously formed by package 370 and package substrate 310. In some embodiments, thermal conductor 380 extends through package substrate 110 but does not further extend, or extends only partially, through package 370. In some other embodiments, thermal conductor 380 is formed or otherwise deposited in hole structure 340 prior to formation of package 370.

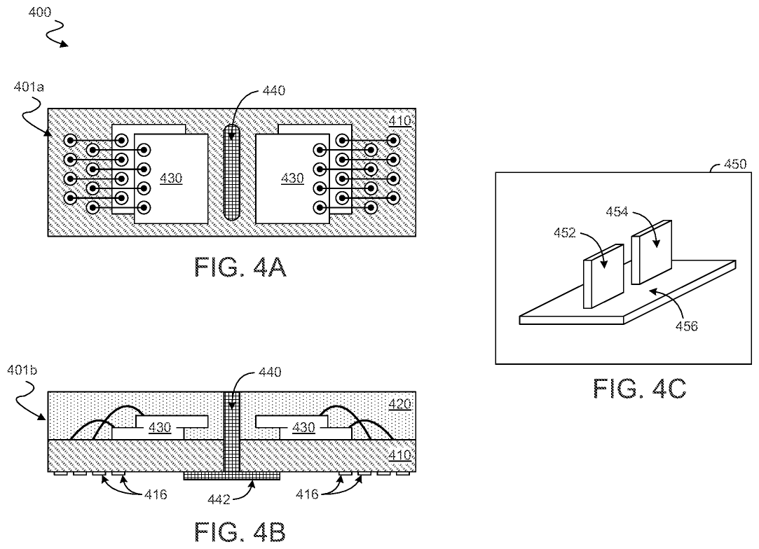

FIG. 4A shows a cross-sectional top view 401a of a packaged IC device 400 to provide heat conduction according to an embodiment. FIG. 4B shows a cross-sectional side view 401b of IC device 400. Packaged IC device 400 may include thermal conductor structures of IC device 100—e.g., wherein fabrication of some or all such structures are provided according to method 200 or processing such as that of stages 300-305.

Packaged device 400 is one example of an embodiment wherein a thermal conductor extends both through a package substrate and between two IC dies coupled to said package substrate. The thermal conductor may include (for example) one or more vertical portions and, in some embodiments, a horizontal planar portion from which the one or more vertical portions variously extend.

In the example embodiment shown, packaged device 400 includes a package substrate 410 and IC dies (such as the illustrative dies 430 shown) coupled thereto. For example, IC dies 430 may be variously wire bonded to contacts (not shown) formed in or on a surface of package substrate 410 which adjoins mold compound 420. The particular number and configuration of IC dies 430 is merely illustrative, and may vary in different embodiments. A mold compound 420 may be disposed on IC dies 430—e.g., wherein mold compound 420 is disposed around IC dies 430 and, in some embodiments, around package substrate 410. Conductive contacts 416 disposed in or on a bottom side of package substrate 410 may facilitate coupling of packaged device 400 to a printed circuit board or other such structure—e.g., where conductors (not shown) formed in package substrate 400 variously couple IC dies 430 to respective ones of contacts 416.

To facilitate heat management with packaged device 400, some embodiments provide a thermal conductor which extends between at least two of IC dies 430. Although some embodiments are not limited in this regard, such a thermal conductor may include a generally planar (or “base”) portion 442 and a fin structure 440 that extends from portion 442. The planar portion 442 may adjoin a bottom side of package substrate 410—e.g., to facilitate conduction of heat to or from an underside of packaged device 400. In an embodiment, planar portion 442 may function as, and/or couple to, a heat dissipator which is to output heat provided from fin structure 440. Alternatively, planar portion 442 may receive heat from other structure (not shown) disposed thereunder, where planar portion 442 is to conduct some or all such heat toward fin structure 440 for conduction through package substrate 410 (and, in some embodiments, through mold compound 420).

In some embodiments, the thermal conductor of packaged device 400 includes a second planar portion (not shown) which is disposed on a top side of mold compound 420—e.g., where the second planar portion is provided in addition to, or instead of, planar portion 442. In other embodiments, the thermal conductor of packaged device 400 omits any such planar portion coupled to fin structure 440.

FIG. 4C illustrates a thermal conductor 450 of packaged device 400 according to another embodiment. Thermal conductor 450 includes a base plate portion 456 and multiple fin structures (such as the illustrative fin structures 452, 454 shown) which extend orthogonally from base plate portion 456. Fin structures 452, 454 may be pick-placed or otherwise disposed each into a respective hole extending through a substrate such as package substrate 410. In some embodiments, fin structures 452, 454 may further extend into a package material (such as mold compound 420)—e.g., wherein fin structures 452, 454 each extend between a different respective pair of IC dies.

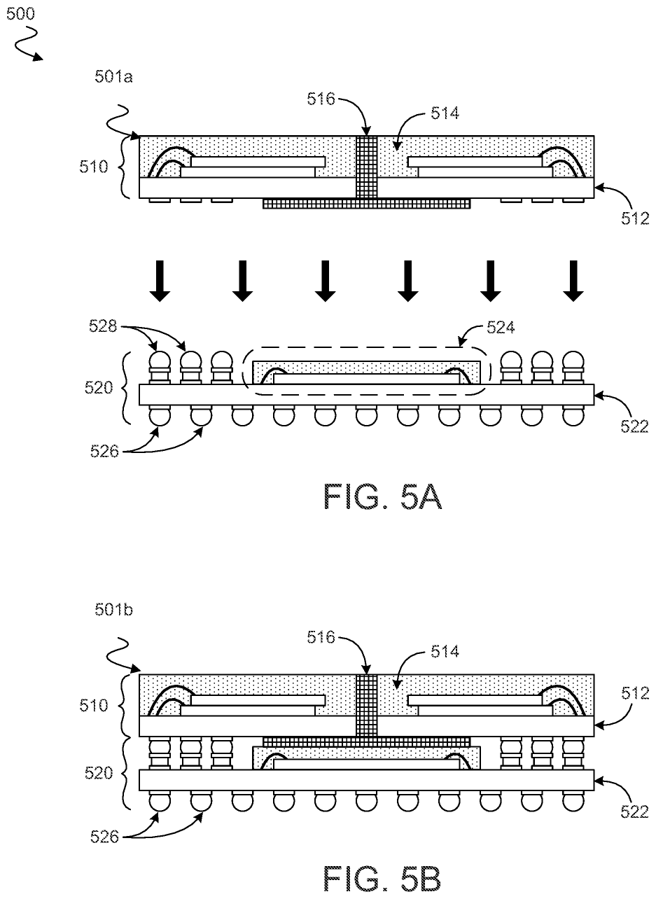

FIGS. 5A-5B show various views of an IC device 500. FIG. 5A shows an assembly view 501a of an IC device 500 to facilitate conduction of heat according to an embodiment. IC device 500 may include structures of one of IC devices 100, 400—e.g., where some or all such structures are provided by method 200 or processing such as that of stages 300-305. FIG. 5B shows an assembled view 501b of IC device 500.

In the example embodiment shown, IC device 500 is a package-on-package (POP) device comprising both a packaged device 510 and another packaged device 520 coupled thereto. Packaged device 510 may include some or all of the features of packaged device 400—e.g., where a package substrate 512, a mold compound 514 and a thermal conductor 516 thereof correspond functionally to package substrate 410, mold compound 420 and the thermal conductor which comprises fin structure 440 and portion 442.

Packaged device 520 illustrates any of a variety of devices to serve as a source (or alternatively, as a sink) of heat which is to be conducted with thermal conductor 516. Packaged device 520 may comprise a package substrate 522 and packaged circuitry 524 disposed thereon, wherein package substrate 522 includes metal layers, vias and/or other conductors which variously interconnect packaged circuitry 524 with contact pads disposed in or on an opposite side of package substrate 522. Solder bumps 526 (or other such interface structures) may enable coupling of IC device 500 to a printed circuit board or other external structure via package substrate 522. Other solder balls 528 disposed, directly or indirectly, on a top side of package substrate 522 may facilitate coupling of packaged device 520 to packaged device 510.

Coupling of packaged devices 510, 520 to each other may include bringing thermal conductor 516 into contact with structure of packaged circuitry 524. Such contact may provide a thermal interface through which packaged devices 510, 520 exchange heat. In one example embodiment, thermal conductor 516 conducts heat from packaged device 520 through each of packaged substrate 512 and mold compound 514 for dissipation of said heat through a top side of IC device 500.

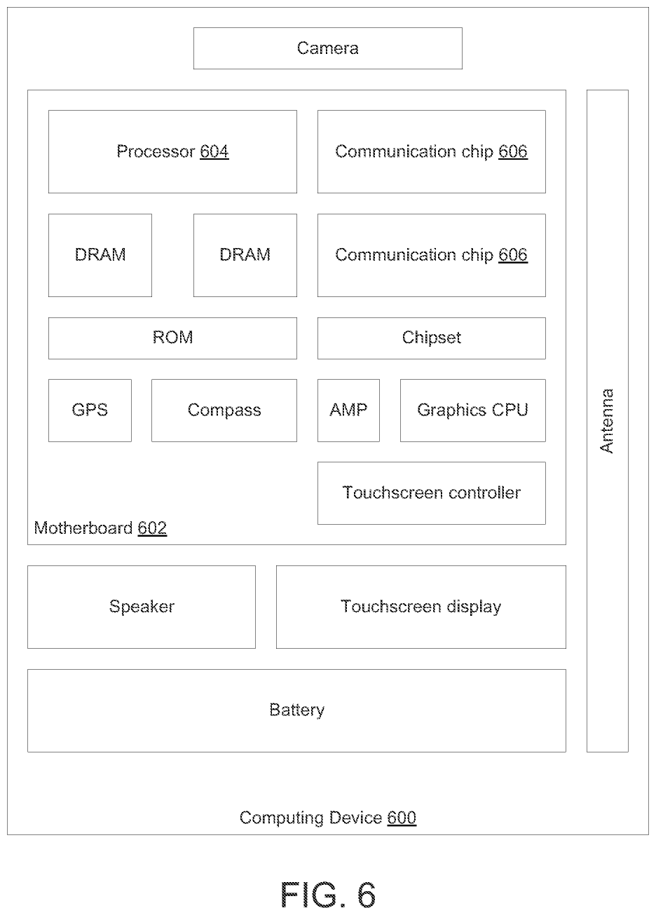

FIG. 6 illustrates a computing device 600 in accordance with one embodiment. The computing device 600 houses a board 602. The board 602 may include a number of components, including but not limited to a processor 604 and at least one communication chip 606. The processor 604 is physically and electrically coupled to the board 602. In some implementations the at least one communication chip 606 is also physically and electrically coupled to the board 602. In further implementations, the communication chip 606 is part of the processor 604.

Depending on its applications, computing device 600 may include other components that may or may not be physically and electrically coupled to the board 602. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 606 enables wireless communications for the transfer of data to and from the computing device 600. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 606 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 600 may include a plurality of communication chips 606. For instance, a first communication chip 606 may be dedicated to shorter range wireless communications such as Wi-Fi and Bluetooth and a second communication chip 606 may be dedicated to longer range wireless communications such as GPS, EDGE, GPRS, CDMA, WiMAX, LTE, Ev-DO, and others.

The processor 604 of the computing device 600 includes an integrated circuit die packaged within the processor 604. The term “processor” may refer to any device or portion of a device that processes electronic data from registers and/or memory to transform that electronic data into other electronic data that may be stored in registers and/or memory. The communication chip 606 also includes an integrated circuit die packaged within the communication chip 606.

In various implementations, the computing device 600 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 600 may be any other electronic device that processes data.

Some embodiments may be provided as a computer program product, or software, that may include a machine-readable medium having stored thereon instructions, which may be used to program a computer system (or other electronic devices) to perform a process according to an embodiment. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

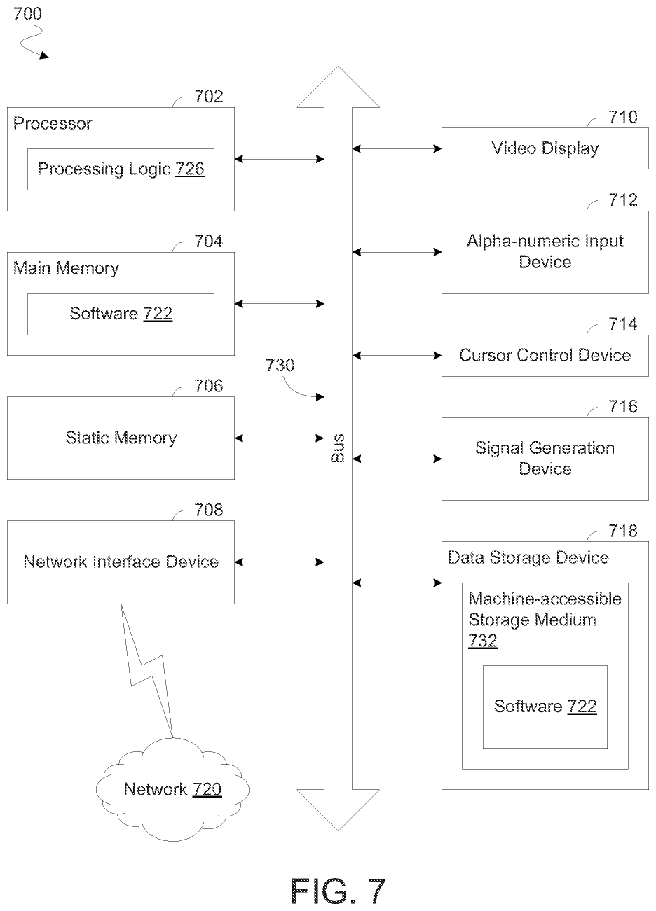

FIG. 7 illustrates a diagrammatic representation of a machine in the exemplary form of a computer system 700 within which a set of instructions, for causing the machine to perform any one or more of the methodologies described herein, may be executed. In alternative embodiments, the machine may be connected (e.g., networked) to other machines in a Local Area Network (LAN), an intranet, an extranet, or the Internet. The machine may operate in the capacity of a server or a client machine in a client-server network environment, or as a peer machine in a peer-to-peer (or distributed) network environment. The machine may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated, the term “machine” shall also be taken to include any collection of machines (e.g., computers) that individually or jointly execute a set (or multiple sets) of instructions to perform any one or more of the methodologies described herein.

The exemplary computer system 700 includes a processor 702, a main memory 704 (e.g., read-only memory (ROM), flash memory, dynamic random access memory (DRAM) such as synchronous DRAM (SDRAM) or Rambus DRAM (RDRAM), etc.), a static memory 706 (e.g., flash memory, static random access memory (SRAM), etc.), and a secondary memory 718 (e.g., a data storage device), which communicate with each other via a bus 730.

Processor 702 represents one or more general-purpose processing devices such as a microprocessor, central processing unit, or the like. More particularly, the processor 702 may be a complex instruction set computing (CISC) microprocessor, reduced instruction set computing (RISC) microprocessor, very long instruction word (VLIW) microprocessor, processor implementing other instruction sets, or processors implementing a combination of instruction sets. Processor 702 may also be one or more special-purpose processing devices such as an application specific integrated circuit (ASIC), a field programmable gate array (FPGA), a digital signal processor (DSP), network processor, or the like. Processor 702 is configured to execute the processing logic 726 for performing the operations described herein.

The computer system 700 may further include a network interface device 708. The computer system 700 also may include a video display unit 710 (e.g., a liquid crystal display (LCD), a light emitting diode display (LED), or a cathode ray tube (CRT)), an alphanumeric input device 712 (e.g., a keyboard), a cursor control device 714 (e.g., a mouse), and a signal generation device 716 (e.g., a speaker).

The secondary memory 718 may include a machine-accessible storage medium (or more specifically a computer-readable storage medium) 732 on which is stored one or more sets of instructions (e.g., software 722) embodying any one or more of the methodologies or functions described herein. The software 722 may also reside, completely or at least partially, within the main memory 704 and/or within the processor 702 during execution thereof by the computer system 700, the main memory 704 and the processor 702 also constituting machine-readable storage media. The software 722 may further be transmitted or received over a network 720 via the network interface device 708.

While the machine-accessible storage medium 732 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any of one or more embodiments. The term “machine-readable storage medium” shall accordingly be taken to include, but not be limited to, solid-state memories, and optical and magnetic media.

In one implementation, an integrated circuit (IC) device comprises a package substrate, one or more IC dies coupled to the package substrate, a mold compound disposed over the one or more IC dies, and a thermal conductor extending through the package substrate and at least partially through the mold compound, the thermal conductor other than any conductor electrically coupled to communicate a signal with the one or more IC dies, wherein the thermal conductor includes or is coupled to a first thermal interface contact at a first side of the package substrate.

In one embodiment, the one or more IC dies include a first IC die disposed within a first plane and a second plane parallel to the first plane, wherein the thermal conductor extends through one or both of the first plane and the second plane. In another embodiment, the thermal conductor further includes or couples to a second thermal interface contact at an exterior side of the IC device, the exterior side opposite the first side. In another embodiment, the one or more IC dies further include a second IC die disposed within the first plane and the second plane, wherein the thermal conductor extends between the first IC die and the second IC die. In another embodiment, the thermal conductor other than any conductor coupled to provide a voltage with the one or more IC dies. In another embodiment, the IC device further comprises a hardware interface at the first side, the hardware interface to couple the IC device to a circuit device. In another embodiment, a first fin structure of the thermal conductor extends through the package substrate and at least partially through the mold compound, the thermal conductor further comprises a second fin structure extending through the package substrate and at least partially through the mold compound, and a planar structure at the first side, wherein the first fin structure is coupled to the second fin structure via the planar structure.

In another implementation, a method comprises coupling one or more integrated circuit (IC) dies to a package substrate, forming a thermal conductor which extends through the package substrate, the thermal conductor other than any conductor electrically coupled to communicate a signal with the one or more IC dies, wherein the thermal conductor includes or is coupled to a first thermal interface contact at a first side of the package substrate, and depositing a mold compound over the one or more IC dies wherein the thermal conductor further extends and at least partially through the mold compound.

In one embodiment, the one or more IC dies include a first IC die disposed within a first plane and a second plane parallel to the first plane, wherein the thermal conductor extends through one or both of the first plane and the second plane. In another embodiment, the thermal conductor further includes or couples to a second thermal interface contact at an exterior side of the IC device, the exterior side opposite the first side. In another embodiment, the one or more IC dies further include a second IC die disposed within the first plane and the second plane, wherein the thermal conductor extends between the first IC die and the second IC die. In another embodiment, the thermal conductor is other than any conductor coupled to provide a voltage with the one or more IC dies. In another embodiment, a first fin structure of the thermal conductor extends through the package substrate and at least partially through the mold compound, wherein the thermal conductor further comprises a second fin structure extending through the package substrate and at least partially through the mold compound, and a planar structure at the first side, wherein the first fin structure is coupled to the second fin structure via the planar structure.

In another implementation, a system comprises an integrated circuit (IC) device including a package substrate,

One or more IC dies coupled to the package substrate, a mold compound disposed over the one or more IC dies, and a thermal conductor extending through the package substrate and at least partially through the mold compound, the thermal conductor other than any conductor electrically coupled to communicate a signal with the one or more IC dies, wherein the thermal conductor includes or is coupled to a first thermal interface contact at a first side of the package substrate. The system further comprises a display device coupled to the IC device, the display device to display an image based on a signal output by the IC device.

In one embodiment, the one or more IC dies include a first IC die disposed within a first plane and a second plane parallel to the first plane, wherein the thermal conductor extends through one or both of the first plane and the second plane. In another embodiment, the thermal conductor further includes or couples to a second thermal interface contact at an exterior side of the IC device, the exterior side opposite the first side. In another embodiment, the one or more IC dies further include a second IC die disposed within the first plane and the second plane, wherein the thermal conductor extends between the first IC die and the second IC die. In another embodiment, the thermal conductor other than any conductor coupled to provide a voltage with the one or more IC dies. In another embodiment, the system further comprises a hardware interface at the first side, the hardware interface to couple the IC device to a circuit device. In another embodiment, a first fin structure of the thermal conductor extends through the package substrate and at least partially through the mold compound, the thermal conductor further comprises a second fin structure extending through the package substrate and at least partially through the mold compound, and a planar structure at the first side, wherein the first fin structure is coupled to the second fin structure via the planar structure.

Techniques and architectures for conducting heat with a packaged device are described herein. In the above description, for purposes of explanation, numerous specific details are set forth in order to provide a thorough understanding of certain embodiments. It will be apparent, however, to one skilled in the art that certain embodiments can be practiced without these specific details. In other instances, structures and devices are shown in block diagram form in order to avoid obscuring the description.

Reference in the specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment.

Some portions of the detailed description herein are presented in terms of algorithms and symbolic representations of operations on data bits within a computer memory. These algorithmic descriptions and representations are the means used by those skilled in the computing arts to most effectively convey the substance of their work to others skilled in the art. An algorithm is here, and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the discussion herein, it is appreciated that throughout the description, discussions utilizing terms such as “processing” or “computing” or “calculating” or “determining” or “displaying” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Certain embodiments also relate to apparatus for performing the operations herein. This apparatus may be specially constructed for the required purposes, or it may comprise a general purpose computer selectively activated or reconfigured by a computer program stored in the computer. Such a computer program may be stored in a computer readable storage medium, such as, but is not limited to, any type of disk including floppy disks, optical disks, CD-ROMs, and magnetic-optical disks, read-only memories (ROMs), random access memories (RAMs) such as dynamic RAM (DRAM), EPROMs, EEPROMs, magnetic or optical cards, or any type of media suitable for storing electronic instructions, and coupled to a computer system bus.

The algorithms and displays presented herein are not inherently related to any particular computer or other apparatus. Various general purpose systems may be used with programs in accordance with the teachings herein, or it may prove convenient to construct more specialized apparatus to perform the required method steps. The required structure for a variety of these systems will appear from the description herein. In addition, certain embodiments are not described with reference to any particular programming language. It will be appreciated that a variety of programming languages may be used to implement the teachings of such embodiments as described herein.

Besides what is described herein, various modifications may be made to the disclosed embodiments and implementations thereof without departing from their scope. Therefore, the illustrations and examples herein should be construed in an illustrative, and not a restrictive sense. The scope of the invention should be measured solely by reference to the claims that follow.

What is claimed is:

1. An integrated circuit (IC) device comprising:
a package substrate;
one or more IC dies coupled to the package substrate;
a mold compound disposed over the one or more IC dies; and
a thermal conductor extending through the package substrate and at least partially through the mold compound, the thermal conductor other than any conductor electrically coupled to communicate a signal with the one or more IC dies, wherein the thermal conductor includes or is coupled to a first thermal interface contact at a first side of the package substrate.

2. The IC device of claim 1, the one or more IC dies including a first IC die disposed within a first plane and a second plane parallel to the first plane, wherein the thermal conductor extends through one or both of the first plane and the second plane.

3. The IC device of claim 2, wherein the thermal conductor further includes or couples to a second thermal interface contact at an exterior side of the IC device, the exterior side opposite the first side.

4. The IC device of claim 2, the one or more IC dies further including a second IC die disposed within the first plane and the second plane, wherein the thermal conductor extends between the first IC die and the second IC die.

5. The IC device of claim 1, the thermal conductor other than any conductor coupled to provide a voltage with the one or more IC dies.

6. The IC device of claim 1, further comprising a hardware interface at the first side, the hardware interface to couple the IC device to a circuit device.

7. The IC device of claim 1, wherein a first fin structure of the thermal conductor extends through the package substrate and at least partially through the mold compound, the thermal conductor further comprising:
a second fin structure extending through the package substrate and at least partially through the mold compound; and
a planar structure at the first side, wherein the first fin structure is coupled to the second fin structure via the planar structure.

8. A method comprising:
coupling one or more integrated circuit (IC) dies to a package substrate;
forming a thermal conductor which extends through the package substrate, the thermal conductor other than any conductor electrically coupled to communicate a signal with the one or more IC dies, wherein the thermal conductor includes or is coupled to a first thermal interface contact at a first side of the package substrate; and
depositing a mold compound over the one or more IC dies wherein the thermal conductor further extends and at least partially through the mold compound.

9. The method of claim 8, wherein the one or more IC dies include a first IC die disposed within a first plane and a second plane parallel to the first plane, wherein the thermal conductor extends through one or both of the first plane and the second plane.

10. The method of claim 9, wherein the thermal conductor further includes or couples to a second thermal interface contact at an exterior side of the IC device, the exterior side opposite the first side.

11. The method of claim 9, wherein the one or more IC dies further include a second IC die disposed within the first plane and the second plane, wherein the thermal conductor extends between the first IC die and the second IC die.

12. The method of claim 8, the thermal conductor other than any conductor coupled to provide a voltage with the one or more IC dies.

13. The method of claim 8, wherein a first fin structure of the thermal conductor extends through the package substrate and at least partially through the mold compound, wherein the thermal conductor further comprises:
a second fin structure extending through the package substrate and at least partially through the mold compound; and
a planar structure at the first side, wherein the first fin structure is coupled to the second fin structure via the planar structure.

14. A system comprising:
an integrated circuit (IC) device including:
a package substrate,
one or more IC dies coupled to the package substrate,
a mold compound disposed over the one or more IC dies, and
a thermal conductor extending through the package substrate and at least partially through the mold compound, the thermal conductor other than any conductor electrically coupled to communicate a signal with the one or more IC dies, wherein the thermal conductor includes or is coupled to a first thermal interface contact at a first side of the package substrate; and
a display device coupled to the IC device, the display device to display an image based on a signal output by the IC device.

15. The system of claim 14, the one or more IC dies including a first IC die disposed within a first plane and a second plane parallel to the first plane, wherein the thermal conductor extends through one or both of the first plane and the second plane.

16. The system of claim 15, wherein the thermal conductor further includes or couples to a second thermal interface contact at an exterior side of the IC device, the exterior side opposite the first side.

17. The system of claim 15, the one or more IC dies further including a second IC die disposed within the first plane and the second plane, wherein the thermal conductor extends between the first IC die and the second IC die.

18. The system of claim 14, the thermal conductor other than any conductor coupled to provide a voltage with the one or more IC dies.

19. The system of claim 14, further comprising a hardware interface at the first side, the hardware interface to couple the IC device to a circuit device.

20. The system of claim 14, wherein a first fin structure of the thermal conductor extends through the package substrate and at least partially through the mold compound, the thermal conductor further comprising:
a second fin structure extending through the package substrate and at least partially through the mold compound; and
a planar structure at the first side, wherein the first fin structure is coupled to the second fin structure via the planar structure.
